(19) United States
(12) Patent Application Publication
(10) Pub. No.: US 2025/0140315 A1
(43) Pub. Date: May 1, 2025

(54) Floating Metal Based Flash Memory

(71) Applicant: ANAFLASH INC., Sunnyvale, CA (US)

(72) Inventor: Seung-Hwan Song, Palo Alto, CA (US)

(21) Appl. No.: 18/924,924

(22) Filed: Oct. 23, 2024

Related U.S. Application Data
(60) Provisional application No. 63/545,637, filed on Oct. 25, 2023.

(51) Int. Cl. G11C 16/04; G11C 16/10; G11C 16/14; G11C 16/26; H10B 41/70

(52) U.S. Cl. CPC G11C 16/0441; G11C 16/10; G11C 16/14; G11C 16/26; H10B 41/70

(57) ABSTRACT

A non-volatile memory cell device is designed with a floating metal node connected through capacitors. The non-volatile synapse memory device comprises: a plurality of input signal lines, including a first word line, a second word line, and a third word line in parallel; a pair of output signal lines in parallel, including a first bit line and a second bit line; a pair of translators, including a write transistor and a read transistor; and a floating metal configured to protect stored charges, wherein the floating metal is a metal node insulated by a plurality of capacitors.

### CROSS-REFERENCE TO RELATED APPLICATIONS

This application claims priority to and the benefit of Provisional U.S. Patent Application No. 63/545,637, filed on Oct. 25, 2023.

### TECHNICAL FIELD OF THE INVENTION

The subject matter disclosed herein generally relates to the field of flash memory devices, and more specifically, to the structure of a new non-volatile memory device that can serve as an alternative to conventional non-volatile memory devices that form a floating gate node.

### BACKGROUND OF THE INVENTION

Flash memory is a type of nonvolatile memory that can store information permanently even when the system power is off. Logic-compatible flash memory is a type of flash memory built using only logic devices.

Memory with a floating gate structure has been used as a logic-compatible flash memory. In memory utilizing a floating gate structure, electrons are injected into the floating gate node during the program operation. During the read operation, the stored data can be recognized by sensing changes in the current flowing through the memory cell due to the electrons trapped in the floating gate.

In logic-compatible flash memory devices, the floating gate transistor is the fundamental building block that allows for non-volatile data storage. The key is that the floating gate is electrically isolated, meaning the charge placed on it remains there even when power is removed. This charge represents the stored bit (0 or 1). Data is written (programmed) using a process called hot-electron injection or Fowler-Nordheim tunneling. A high voltage is applied between the control gate and the source/drain. This creates a strong electric field that accelerates electrons from the channel region.

Some of these high-energy electrons tunnel through the thin oxide layer and become trapped on the isolated floating gate. The number of trapped electrons represents the stored bit. Specifically, Logic 1 is the status where a sufficient number of electrons are injected into the floating gate, creating a significant negative charge. This charge influences the channel, raising the threshold voltage of the connected transistor and causing a smaller current to flow through the transistor when the read voltage is applied compared to when electrons are not trapped in the floating gate.

Logic 0 is the status where few or no electrons are injected. The floating gate remains essentially neutral. Since the transistor has an intrinsic threshold voltage, a larger current flows through the transistor when the read voltage is applied compared to when electrons are trapped in the floating gate. The process needs precise voltage control to ensure the correct number of electrons are injected for reliable data storage. Logic compatibility here means the programming voltage is higher than the typical logic voltage levels, but still within a range that is manageable with standard semiconductor fabrication processes.

Conventional logic-compatible flash memory, designed for integration with logic circuits, typically uses smaller transistors and thinner oxides to increase density and performance. These very design features that enhance performance also make it more susceptible to electron leakage. The smaller feature sizes lead to higher electric fields, accelerating FNT and direct tunneling. Electron leakage in the floating gate of logic-compatible flash memory devices is a significant reliability concern. It is a phenomenon where electrons stored on the floating gate, representing the stored data (0 or 1), gradually leak away over time, leading to data corruption and ultimately memory failure. This leakage impacts the longevity and data retention capability of the flash memory, stemming from the inherent nature of floating-gate transistors used in flash memory cells.

As the gate oxide of MOSFETs becomes even thinner, this issue will worsen, creating the need for a new memory structure that can replace logic-compatible flash memory with a floating gate structure. To address the critical challenges in the design and operation of logic-compatible flash memory, this invention introduces a new structure of logic-compatible flash memory that can replace the conventional floating gate memory.

### SUMMARY OF INVENTION

This invention discloses a logic-compatible flash memory device, and more particularly, an improved flash memory device to mitigate electron leakage in flash memory.

According to the present invention, A non-volatile synapse memory device comprises a plurality of input signal lines, including a first word line, a second word line, and a third word line in parallel; a pair of output signal lines in parallel, including a first bit line and a second bit line; a pair of transistors, including a read transistor and a write transistor; and a floating metal configured to protect stored charges, wherein the floating metal is a metal node insulated by a plurality of capacitors.

According to some embodiments, the read transistor and write transistor are NMOS transistors.

According to some embodiments, a first and second capacitors are connected in series, and a third capacitor is connected to the floating metal between the first and second capacitors.

According to some embodiments, the first capacitor is relatively larger than the second capacitor and the third capacitor.

According to some embodiments, the first capacitor is connected to the second word line and the floating metal; the second capacitor is connected to the third word line and the floating metal; and the third capacitor is connected to the floating metal and a gate node that is connected to a source region of the write transistor and a gate of the read transistor.

According to some embodiments, the write transistor has a drain region connected to the first bit line, a source region connected to the gate node, and a gate connected to the first word line.

According to some embodiments, the read transistor has a drain region connected to the second bit line, a source region connected to ground, and a gate connected to the gate node.

According to one embodiment, a method of erasing the non-volatile synapse memory device comprises the steps of: applying a ground voltage to the first bit line; applying a supply voltage to the gate of the write transistor for turning on the read transistor; applying a ground voltage to the second word line for causing a voltage condition in the floating metal to approximately zero voltage; and applying a predetermined high voltage to the third word line to remove electrons in the floating metal.

According to one embodiment, a method of programming non-volatile synapse memory device comprises the steps of: applying a ground voltage to the first bit line; activating the write transistor by applying a power supply voltage to a gate of the write transistor for setting the gate node to zero volt; and applying a preset high voltage to the second word line and the third word line for causing a voltage condition in the floating metal to approximate the high voltage for injecting electrons into the floating metal through the third capacitor due to the strong electric field between the gate node and the floating metal.

According to one embodiment, a method of programming the non-volatile synapse memory device comprises the steps of: applying a power supply voltage to the first bit line; deactivating the write transistor by applying a power supply voltage to a gate of the write transistor for prohibiting electron injection from the gate node into the floating metal; and applying a preset high voltage to the second and third word lines for causing a voltage condition in the floating metal to approximate the high voltage and a voltage condition of the gate node to approximate half of the high voltage.

According to one embodiment, a method of reading non-volatile synapse memory device comprises the steps of: applying a ground voltage to the gate terminal of the write transistor to deactivate the write transistor; applying a preset read voltage to the second word line and the third word line; and measuring current flows in the second bit line.

### BRIEF DESCRIPTION OF THE DRAWINGS

FIG. 1 is a block diagram illustrating a basic cell structure of the proposed non-volatile flash memory according to one embodiment of the present invention.

FIG. 2 is an overall block diagram of a non-volatile memory macro having the proposed non-volatile memory cell according to one embodiment of the present invention.

FIG. 3 is a circuit diagram showing a bias condition during an erase operation of the non-volatile memory cell according to one embodiment of the present invention.

FIGS. 4A and 4B are a circuit diagram and a program bias timing diagram of programming the non-volatile memory cell to logic low “L” according to one embodiment of the present invention.

FIGS. 5A and 5B are a circuit diagram and a program bias timing diagram of programming the non-volatile memory cell to logic high “H” according to one embodiment of the present invention.

FIG. 6 is a circuit diagram showing a bias condition during a read operation of the non-volatile memory cell according to one embodiment of the present invention.

### DETAILED DESCRIPTION OF THE INVENTION

In the following detailed description of the invention, reference is made to the accompanying drawings that form a part hereof, which is shown by way of illustration and specific embodiment. In the drawings, like numerals, features of the present invention will become apparent to those skilled in the art from the following description of the drawings. Understanding that the drawings depict only typical embodiments of the invention and are not, therefore, to be considered limiting in scope, the invention will be described with additional specificity and detail through the accompanying drawings.

Terms containing ordinal numbers, such as first, second, etc., may describe various components, but the terms do not limit the components. The above terms are used only to distinguish one component from another.

When a component is said to be “connected” or “accessed” to another component, it may be directly connected to or accessed to the other component, but it should be understood that other components may exist in between. On the other hand, when it is mentioned that a component is “directly connected” or “directly accessed” to another component, it should be understood that there are no other components in between.

Singular expressions include plural expressions unless the context clearly dictates otherwise.

In this application, it should be understood that terms such as “comprise” or “have” are meant to indicate the presence of features, numbers, steps, operations, components, parts, or combinations thereof described in the specification; however, these terms do not exclude the possibility of the additional features, numbers, steps, operations, components, parts, or combinations thereof existing or being added in advance.

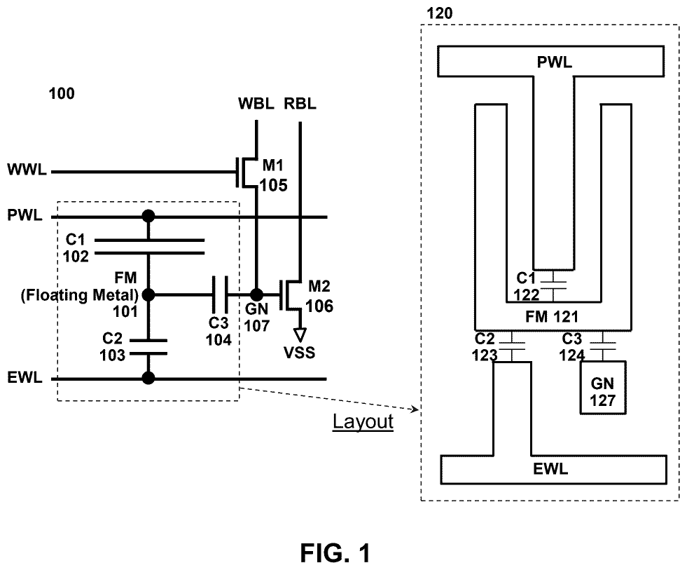

FIG. 1 is a schematic of a memory cell of proposed non-volatile flash memory and a corresponding sample layout according to one embodiment of the present invention.

In the memory cell 100, a floating metal 101 for storing charge and thus representing the binary data (0 or 1) is isolated by three capacitors C1, C2, and C3. The capacitors C1 102, C2 103, and C3 104 are metal-to-metal capacitors (e.g., MIM, MOM, etc.), which can be formed using laterally or vertically placed metal lines, or alternatively using parasitic capacitors from the metal lines.

The capacitor C1 102 has a larger capacitance value than the capacitors C2 103 and C3 104, thus, the floating metal (FM, 101) can be more strongly coupled to the PWL bias. A write transistor M1 105 and a read transistor M2 106 can be fabricated using logic devices without adding any process overhead to the CMOS logic process.

WWL, PWL, and EWL are word lines that deliver voltages to the memory cell 100 for reading, erasing and writing. Gate node (GN) 107 is connected to the gate of the read transistor M2 106, and VSS refers to ground voltage (GND).

WBL is a bit line that delivers voltage to the memory cell 100 during erase and program operation. RBL is a bit line used during the read operation to sense current and read the data stored in the memory cell 100. The voltages applying to the memory cell 100, the read, program, and erase operations, as well as current sensing on the bit line RBL for reading the data stored in the memory cell, will be explained in the following sections.

The write transistor M1 105 is an NMOS, with its drain connected to WBL and its source connected to the gate node (GN, 107) of the read transistor M2 106. The gate of M1 105 is connected to WWL. The read transistor M2 106 is also an NMOS, with its drain connected to RBL, its source connected to VSS, and its gate connected to GN 107. One terminal of capacitor C1 102 is connected to PWL, while the other terminal is connected to the floating metal (FM, 101). The FM 101 is connected not only to C1 102 but also to one terminal of both C2 103 and C3 104. The other terminal of C2 103, which is not connected to the FM 101, is connected to EWL, while the other terminal of C3 104, which is not connected to the FM 101, is connected to GN 107.

A diagram 120 shows a sample layout of the floating metal (FM) 101 and capacitors C1 102, C2 103, and C3 104. All lines in the sample layout are metal lines. While FM 121 is not electrically connected to PWL, EWL, or a gate node (GN) 127, the capacitors C1 122, C2 123, and C3 124 are formed due to parasitic capacitance between the metal lines. As seen in the sample layout, the capacitor C1 122 has a larger capacitance compared to the capacitors C2 123 and C3 124 because it is formed through a wider area between a floating metal (FM) 121 and a program word line PWL, whereas capacitors C2 123 and C3 124 are formed through narrower areas. A capacitor C2 123 is the parasitic capacitor between the floating metal (FM) 121 and an erase word line (EWL), and a capacitor C3 124 is the parasitic capacitor between the floating node FM 121 and the gate node (GN) 127.

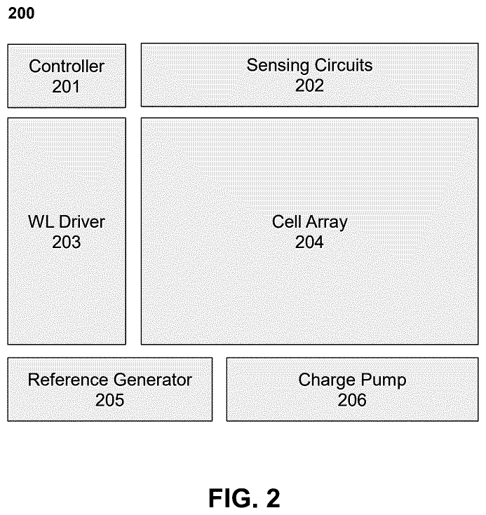

FIG. 2 shows an overall block diagram 200 of the non-volatile memory macro having the proposed non-volatile memory cell 100. A charge pump 206 and a word line (WL) driver 203 shall be implemented using core logic devices or I/O devices for higher reliability. Multi-stacking, multi-staging techniques can be used to limit the voltage stress of the individual transistor.

A controller 201 performs the role of controlling the overall block 200 according to one embodiment of the present invention. For instance, the controller 201 may supervise translating a logic address into the physical address used to access the memory cells 100. The controller 201 may control selecting the specific row and column within the memory cell array 202 that needs to be accessed, which is crucial for enabling read/write operation to only the desired location. The controller 201 may control boosting the weak read from the memory cells to a level usable by the rest of the system 100 for read operations. The controller 201 may control proving the necessary current or voltage levels to write data into the selected memory cells in the cell array 204 for write operations. The controller 201 may control buffers (not shown) for temporarily holding data being written to or read from the memory array 204. The controller 201 may coordinate the actions of all other components in the memory macro 200. That is, the controller 201 may generate the necessary control signals for the address decoder (not shown), row/column selectors (not shown), sense amplifier (not shown), and word line driver 203, and manage data flow. The controller 201 can also handle timing and error detection/correction if implemented.

The cell array 204 contains multiple proposed memory cells 100, and the numerous memory cells 100 form a plurality of rows and columns within the cell array 204. Sensing circuits 202 sense the current flowing through the memory cells 100 (reading the data stored in the memory cells 100) to detect whether the stored charges in the memory cells 100 correspond to a programmed or erased state during the read operation. The word line driver 203 (WL Driver) drives the voltages of the word lines, WWL, PWL, and EWL, applied to the memory cells 100.

A reference generator 205 supports the other circuits by generating a reference signal level (i.e., VRD) during the read operation. During the program and erase operations of the memory cell 100, a high voltage is required to inject and eject electrons into and from the Floating Metal 101 (FM). The charge pump 206 generates the high voltage that the supply voltage (Vdd) for specific operations (i.e., programming or reading operations) within the memory cell array 204.

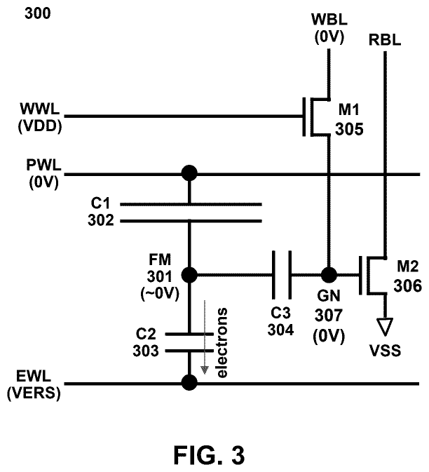

FIG. 3 shows a bias condition during an erase operation of the non-volatile memory cell 300. The voltage of the write bit line WBL connected to the write transistor M1 305 is 0V, and since VDD is applied to WWL, the gate voltage of M1 305, M1 305 turns on, causing the voltage of GN 307 connected to C3 304 and the gate of M2 306 to become 0V. 0V is applied to PWL, which is connected to C1 302, and the erase voltage VERS is applied to EWL, which is connected to C2 303. Since the capacitance of C1 302 is much larger than that of C2 303, C1 302 becomes the dominant capacitor, resulting in the FM 301 node voltage being approximately 0V. As the FM 301 node voltage is approximately 0V and the high voltage VERS is applied to EWL, the electrons that were injected into FM 301 during the program operation are ejected through C2 303. Through this operation, the non-volatile memory cell 300 is erased. As described above, since the voltage of GN 307, the gate of the NMOS read transistor M2 306, is 0V, M2 306 is turned off, and no current flows through the read bit line RBL.

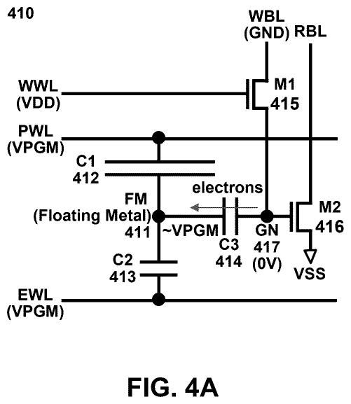

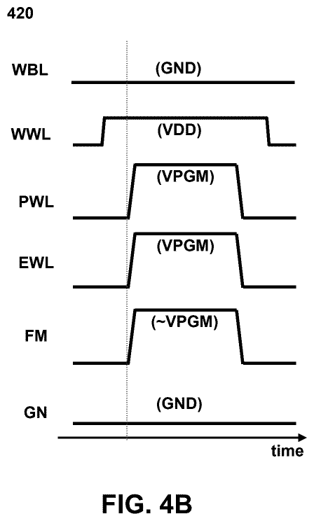

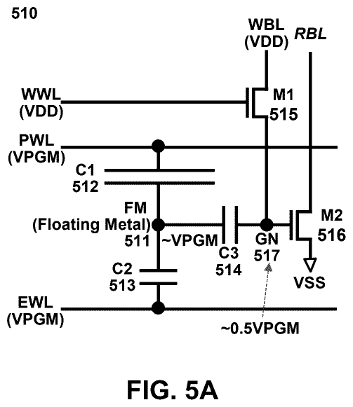

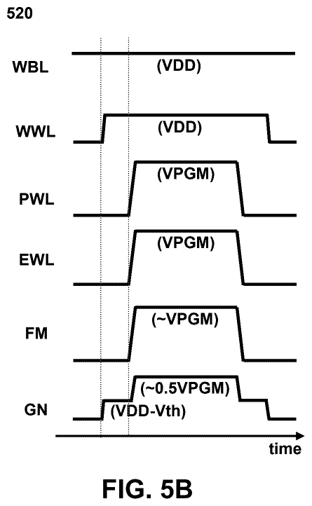

FIGS. 4A. 4B and FIGS. 5A, 5B show a bias condition of a program operation of the non-volatile memory cell according to some embodiments of the present invention.

FIGS. 4A and 4B are a schematic of a memory cell 410 and program bias timing diagram 420 for programming the non-volatile memory cell 100 to logic low “L” by injecting electrons into a floating metal (FM) 411 during a program operation. In FIG. 4A, when 0V is applied to WBL, and VDD is applied to WWL for logic low “L”, a write transistor M1 415 turns on, causing the voltage of a gate node (GN) 417 connected to the gate of a read transistor M2 416 to become 0V. At this point, if the high program voltage VPGM is applied to both PWL and EWL coupled to a capacitor C1 412 and a capacitor C2 413, respectively, the voltage of a floating metal (FM) 411 becomes approximately VPGM. This creates a strong electric field across a capacitor C3 414 between the floating node (FM) 411 and the gate node (GN) 417, leading to the injection of electrons into the floating metal (FM) 411 through a capacitor (C3) 414. In FIG. 4B, a timing diagram 420 of the program bias used to program the non-volatile memory cell 410 to logic low “L” during the program operation.

FIGS. 5A and 5B are a schematic diagram of a memory cell 510 and program bias timing diagram 520 for programming the non-volatile memory cell 100 to logic high “H” by prohibiting electron injection into a floating metal (FM) 511 during a program operation.

In FIG. 5A, when VDD is applied to both WBL and WWL for logic high “H”, the voltage of a gate node (GN) 517 becomes VDD-Vth, and the write transistor M1 515 is turned off. At this point, when the high program voltage VPGM is applied to both PWL and EWL coupled to a capacitor C1 512 and a capacitor C2 513 respectively, the voltage of the floating metal (FM) 511 becomes approximately VPGM. If the parasitic capacitance of the read transistor M2 516 from a gate node (GN) 517 to VSS is similar to a capacitor C3 514 between the gate node (GN) 517 and the floating metal (FM) 511, the voltage of the gate node (GN) 517 becomes ˜0.5 VPGM. Therefore, unlike in the case of logic low “L,” a strong electric field is not formed across C3 514, which prevents the injection of electrons into the floating metal (FM) 511. In FIG. 5B, the timing diagram 520 of the program bias used to program the non-volatile memory cell 510 to logic high “H” during the program operation.

The cell array 204 comprises multiple rows and columns, with each row and column containing multiple non-volatile memory cells 100. During the program operation, by applying VDD to the WWL and VPGM to both PWL and EWL of each row, the voltage applied to the WBL of each non-volatile memory cell 100 can be set to either 0V or VDD. This allows for selecting whether to program each non-volatile memory cell 100 to logic low “L” or logic high “H” in the same row.

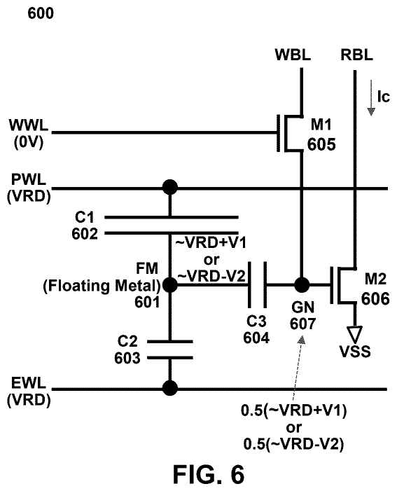

FIG. 6 shows a bias condition during a read operation of the non-volatile memory cell 600 according to one embodiment of the present invention. The read voltage, VRD, is applied to coupling capacitors C1 602 and C2 603 through the PWL and EWL word lines. When the non-volatile memory cell 600 is erased, a floating metal (FM) 601 node is free of electrons and the floating metal (FM) 601 node can have some positive voltage V1 when VRD is driven to 0V. Due to the large coupling of C1 602, the voltage of the floating metal (FM) 601 node becomes approximately VRD plus a positive V1 (˜VRD+V1) during the read operation. If the capacitance from a gate node (GN) 607 to VSS is similar to the capacitor C3 604 between the gate node (GN) 607 and the floating metal (FM) 601, the voltage at the gate node (GN) 607 becomes 0.5(˜VRD+V1). On the other hand, when the non-volatile memory cell 600 is programmed, the floating metal (FM) 601 node is filled with electrons and the floating metal (FM) 601 node can have some negative voltage −V2 when VRD is driven to 0V. Due to the large coupling of C1 602, the voltage of the floating metal (FM) node becomes approximately VRD plus a negative V2 (˜VRD−V2) during the read operation. Similar to the erased state, if the capacitance from the gate node (GN) 607 to VSS is comparable to the capacitor C3 604 between the gate node (GN) 607 and the floating metal (FM) 601, the voltage at the gate node (GN) 607 becomes 0.5(˜VRD−V2). The read transistor M2 606 is an NMOS, and during the read operation, the voltage at the gate node (GN) 607 varies by 0.5 (V1+V2) (=0.5(˜VRD+V1)−0.5(˜VRD−V2)) between the two erased and programmed states of the non-volatile memory cell 600. Since in NMOS, more current flows when the gate voltage is higher, the sensing circuits 202 can detect whether the cell is in an erased or programmed state by measuring the current, Ic, flowing through the read transistor M2 606 on the read bit line RBL from the sensing circuits 202. The WWL applied to the gate of the write transistor M1 605 is 0V, and since the write transistor M1 605 is also an NMOS, it is turned off and the voltage of the write bit line WBL is ‘don't care’.

What is claimed is:

1. A non-volatile synapse memory device comprising:
a plurality of input signal lines, including a first word line, a second word line, and a third word line in parallel;
a pair of output signal lines in parallel, including a first bit line and a second bit line;
a pair of transistors, including a read transistor and a write transistor; and
a floating metal configured to protect stored charges, wherein the floating metal is a metal node insulated by a plurality of capacitors.

2. The non-volatile synapse memory device of claim 1, wherein the read transistor and write transistor are NMOS transistors.

3. The non-volatile synapse memory device of claim 2, wherein a first and second capacitors are connected in series, and a third capacitor is connected to the floating metal between the first and second capacitors.

4. The non-volatile synapse memory device of claim 3, wherein the first capacitor is relatively larger than the second capacitor and the third capacitor.

5. The non-volatile synapse memory device of claim 4, wherein the first capacitor is connected to the second word line and the floating metal;
the second capacitor is connected to the third word line and the floating metal; and
the third capacitor is connected to the floating metal and a gate node that is connected to a source region of the write transistor and a gate of the read transistor.

6. The non-volatile synapse memory device of claim 5, wherein the write transistor has a drain region connected to the first bit line, a source region connected to the gate node, and a gate connected to the first word line.

7. The non-volatile synapse memory device of claim 6, wherein the read transistor has a drain region connected to the second bit line, a source region connected to ground, and a gate connected to the gate node.

8. A method of erasing the non-volatile synapse memory device of claim 7, comprising:
applying a ground voltage to the first bit line;
applying a supply voltage to the gate of the write transistor for turning on the read transistor;
applying a ground voltage to the second word line for causing a voltage condition in the floating metal to approximately zero voltage; and
applying a predetermined high voltage to the third word line to remove electrons in the floating metal.

9. A method of programming non-volatile synapse memory device of claim 7, comprising:
applying a ground voltage to the first bit line;
activating the write transistor by applying a power supply voltage to a gate of the write transistor for setting the gate node to zero volt; and
applying a preset high voltage to the second word line and the third word line for causing a voltage condition in the floating metal to approximate the high voltage for injecting electrons into the floating metal through the third capacitor due to the strong electric field between the gate node and the floating metal.

10. A method of programming the non-volatile synapse memory device of claim 7, comprising:
applying a power supply voltage to the first bit line;
deactivating the write transistor by applying a power supply voltage to a gate of the write transistor for prohibiting electron injection from the gate node into the floating metal; and
applying a preset high voltage to the second and third word lines for causing a voltage condition in the floating metal to approximate the high voltage and a voltage condition of the gate node to approximate half of the high voltage.

11. The method of reading non-volatile synapse memory device of claim 7, comprising:
applying a ground voltage to the gate terminal of the write transistor to deactivate the write transistor;
applying a preset read voltage to the second word line and the third word line; and
measuring current flows in the second bit line.
